(19) United States
(12) Patent Application Publication
(10) Pub. No.: US 2011/0011802 A1
(43) Pub. Date: Jan. 20, 2011

(54) SYSTEMS AND METHODS FOR SIMULTANEOUSLY GENERATING ENERGY AND TREATING WATER

(76) Inventor: Dan MAYDAN, Los Altos Hills, CA (US)

Correspondence Address: NIXON PEABODY, LLP, 401 9TH STREET, NW, SUITE 900, WASHINGTON, DC, 20004-2128, US

(21) Appl. No.: 12/838,333

(22) Filed: Jul. 16, 2010

Related U.S. Application Data
(60) Provisional application No. 61/226,680, filed on Jul. 17, 2009.

(51) Int. Cl. C02F 1/00; C02F 1/58; C02F 1/44; H01L 31/0232; F28D 15/00

(52) U.S. Cl. 210/652; 210/747; 210/175; 422/38; 136/259; 165/104.33; 417/53

(57) ABSTRACT

A system that enables cooling a concentrated photovoltaic cell, while simultaneously treating water, e.g., desalinating sea water. A concentrated PV panel converts solar energy to electric power. Recirculated water e.g., reclaimed or sea water, at an optimized temperature range flows into the PV panel to cool the solar PV cells. The recirculated water is heated by the PV panel and is then directed to a water treatment unit, e.g., a heat exchanger or water desalinator. The water treatment unit may be a high temperature reverse osmosis (RO) unit, or a bacterial water treatment plant. A flow of water to be treated enters the heat exchanger/desalinator unit. Heat from the heated recirculated water is used to treat the cooler water.

### CROSS-REFERENCE TO RELATED APPLICATION

This application claims the benefit of priority from U.S. Provisional Patent Application No. 61/226,680 filed on Jul. 17, 2009, the entire disclosure of which is relied upon and incorporated by reference herein.

### BACKGROUND

1. Field

The subject invention relates to methods and systems for generating electrical power from renewable energy sources, such as the sun and natural resources of water, and using natural water as a thermal management fluid and a potable water source.

2. Related Art

Recently, efforts have been made to increase the energy generated by photovoltaic panels by concentrating solar energy onto PV solar panels using, e.g., a set of mirrors or lenses. The idea is that the more sun energy is focused onto the photovoltaic cell, the more energy can be harvested by the photovoltaic cell. Such systems are generally referred to as concentrated PV systems. Solar concentrators have also been employed to concentrate the sun energy to heat water that is then used to generate electricity by, e.g., operating a turbine. Since these hydro-solar systems heat water, some to very high temperatures, it has been proposed to use such systems to also desalinate the water, i.e., flow salt water in the system and use the steam to both run a turbine and then condense to desalinated water.

### SUMMARY

A system that enables cooling a concentrated photovoltaic cell, while simultaneously treating water, e.g., desalinating sea water. A concentrated PV panel converts solar energy to electric power. Recirculated water e.g., reclaimed or sea water, at an optimized temperature range flows into the PV panel to cool the solar PV cells. The recirculated water is heated by the PV panel and is then directed to a water treatment unit, e.g., a heat exchanger or water desalinator. The water treatment unit may be a high temperature reverse osmosis (RO) unit, a sub-atmospheric evaporator, or a bacterial water treatment plant. A flow of water to be treated enters the heat exchanger/desalinator unit. Heat from the heated recirculated water is used to treat the cooler water.

### BRIEF DESCRIPTION OF THE DRAWINGS

The accompanying drawings, which are incorporated in and constitute a part of this specification, exemplify the embodiments of the present invention and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements, and are not drawn to scale. In the specification and claims, the term sea water encompasses natural resources of water from which salt needs to be removed in order to make it potable.

FIG. 1 shows one embodiment of a system for concentrated photovoltaic power generation and treatment of water, e.g., desalination of sea water.

FIG. 2 shows another embodiment of a system for concentrated photovoltaic power generation and desalination of sea water.

FIG. 3 illustrates an embodiment beneficial for operation at an industrial plant.

FIG. 4 illustrates an embodiment wherein the PV system is integrated into a water pumping facility and is used to both energize the water pump and for treating the pumped water.

FIG. 5 illustrates an embodiment wherein the PV system is integrated into an industrial plant and is used to heat a bacterial water treatment plant.

FIG. 6 shows a map of the geographical region between the Mediterranean sea and the Dead Sea, while FIG. 7 is a close-up of the region where a cross-section A-A of FIG. 8 is taken.

FIG. 8 is a not-to-scale cross-section along line A-A of FIG. 7, schematically illustrating an example embodiment of bringing sea water to a region with scarce supply of fresh water.

FIG. 9 represents the main aquifers in the Negev region from the Mediterranean Sea in the west to the Dead Sea on the east.

FIG. 10 represents a vertical hydrological cross-section of about 20 km, west to the Dead Sea.

### DETAILED DESCRIPTION

Embodiments of the invention operate to effectively resolve two problems. First, it has been found that the conversion efficiency of photovoltaic cells fall as the photovoltaic cells' temperature increases. Therefore, while concentrated PV system makes more sun energy available to the photovoltaic cells to harvest, the concentrated sun energy also raises the temperature of the photovoltaic cells, thereby reducing the conversion efficiency. Consequently, a solution needs to be found to maximize the conversion efficiency of the PV cell, while allowing the concentrators to provide the maximum solar energy to the cell. Second, in addition to the need for a clean renewable energy, the world also faces a significant shortage of potable water. While water desalination plants have been developed, they are still very expensive to build and operate. Also, solar desalination has been so far limited to concentrated hydro-solar systems, which are industrial in nature.

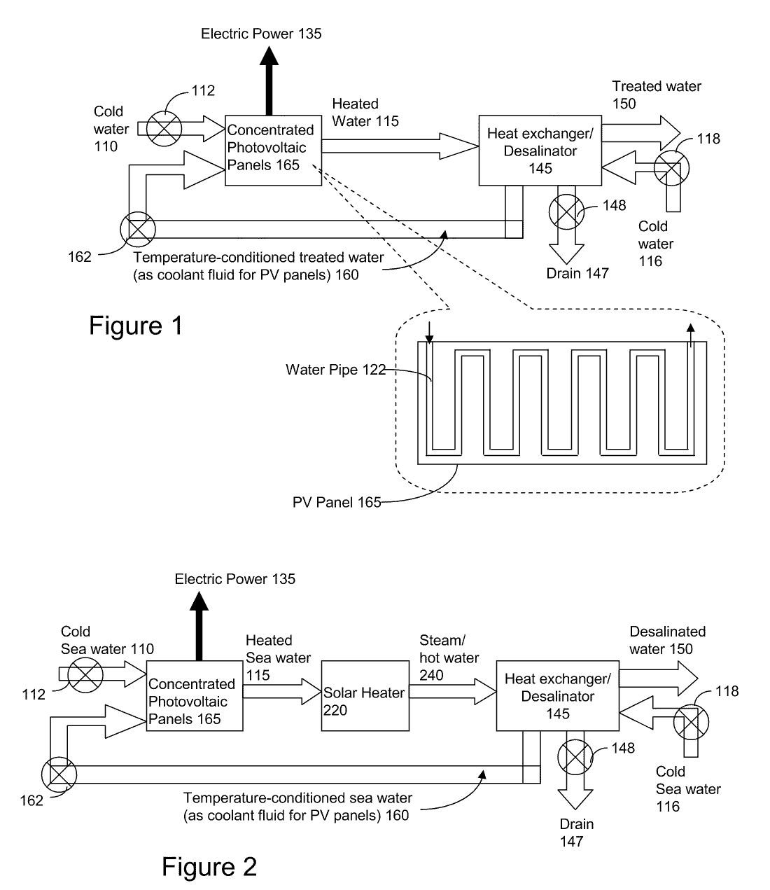

FIG. 1 provides a solution that enables cooling the concentrated photovoltaic cell, while simultaneously treating water, e.g., desalinating sea water. In general, the system uses two separate loops, one for PV cell cooling and one for water treatment. As shown in FIG. 1, concentrated PV panels 165 converts solar energy to electric power 135. An example embodiment of PV panel 165 may generate 10-100 MW electric power from sun energy concentrated on the panels using mirrors and/or lenses. However, since it uses standard solar cells, it can also be made into small and even portable system. Recirculated water 160 (e.g., reclaimed or sea water) at an optimized temperature range (for example 50-90° C.) flows into the PV panel 165 via a valve 162 to cool the concentrated solar PV cells. For example, the sea water can be flowed in pipes or tubes attached to the back of the PV panels to act as heat exchanger. An example is shown in the callout, wherein water flows in pipes 122 that are attached to the back of the PV panel 165.

It is to be noted that the solar PV cells work most efficiently at temperatures lower than 70° C. Thus, temperature conditioning of the recirculated water 160 is important. In an example embodiment, an optional flow of fresh cold, e.g., sea water 110 (at around 20° C.) may be directed to the PV panel 165 through a valve 112. Valves 112 and 162 may be used to regulate flows of fresh sea water 110 and recirculated sea water 160, so that optimum temperature conditioning is achieved. For example, if the recirculated sea water 160 becomes too hot, cold sea water 110 may be mixed with it to bring down the temperature. In another example, the flow rates of sea waters 110 and 160 may be varied at different times of the day. For example, during high noon when the PV panels become too hot, high amount of cold sea water 110 may be mixed with the recirculated sea water 160 to bring down the panels' temperature. On the other hand, in early morning or late afternoon the panels may not get too hot, and the amount of cold sea water may be reduced or eliminated.

Sea water 115 at the output of the PV panel 165 absorbs some of the heat from the PV cells in the PV panel 165, and reaches a higher temperature, for example around 80° C. or higher. Heated sea water 115 is directed to a heat exchanger/desalinator unit 145, which may be atmospheric or sub-atmospheric unit. Desalinator 145 may also be a high temperature reverse osmosis (RO) unit. A flow of cold (around 20° C.) water 116 to be treated enters the heat exchanger/desalinator unit 145 through a valve 118. This may be, for example, recycled water or sea water. Heat from the heated sea water 115 is transferred to the cooler sea water 116 inside the heat exchanger/desalinator unit 145.

Water treatment and/or desalination processes may vary. Desalination may be based on evaporation (requires high heat), reverse osmosis (requires high pressure and a semi-permeable membrane), centrifugal force (requires rotating mechanical parts), or a combination thereof, as known by persons skilled in the art. Other conventional processes of desalination may be adopted as well, while conventional heat exchanges may be used to transfer the heat from heated water 115 to cold water 116. One or more of the heat and pressure of the heated water or steam may be utilized for the treatment and/or desalination process depending on the system's particular desalination mechanism. Persons skilled in the art will also understand that although the heat exchanger/desalinator unit 145 is shown as a single component, it may be divided into multiple functional chambers.

In one desalination embodiment based on evaporation followed by condensation, the cool sea water 116 gets heated and then evaporated by absorbing heat in the heat exchanger. The distilled (without salt or with much lower salt concentration) vapor or steam portion of the sea water 116 goes into a condenser chamber located inside or outside the unit 145, and eventually comes out from the condenser as treated/desalinated water 150. Treated/desalinated water 150 may or may not need further filtering in order to be potable.

The concentrated salt water (portion of the sea water 116) remaining at the bottom of the unit 145 comes out as part of recirculated sea water 160 that cools the PV panel 165, or is drained out through drain 147 and valve 148. Valve 148 helps conditioning the temperature of the recirculated sea water 160 by regulating the amount of drainage. Drain 147 may also drain out excess salt slurry to reduce the possibility of corrosion in the PV panel 165 by the recirculated sea water 160. Once the heated sea water 115 loses a portion of its heat inside the heat exchanger, it also comes out as part of recirculated sea water 160 from the bottom of the unit 145, or is drained out. Recirculated sea water 160 is pumped back to the PV panel 165 as a coolant fluid.

In an alternative embodiment shown in FIG. 2, heated sea water 115 first gets into a solar heater 220 to get a temperature and/or pressure boost. Heater 220 may be eliminated or its boost reduced if a sub-atmospheric heat exchanger/desalinator 145 is used. On the other hand, if a high temperature reverse osmosis (RO) unit is used, it may operate more efficiently at higher temperatures. Solar heater 220 may be of hydro-solar type heater, and may employ one or more reflectors/mirrors and/or other optical elements (not shown specifically) to concentrate solar thermal energy to heat up sea water 115 further. Excess salt slurry may be drained out from the solar heater 220 before going to the heat exchanger/desalinator unit 145. The output of the solar heater 220 may be a mixture of steam and hot water in the temperature range of 80-110° C.

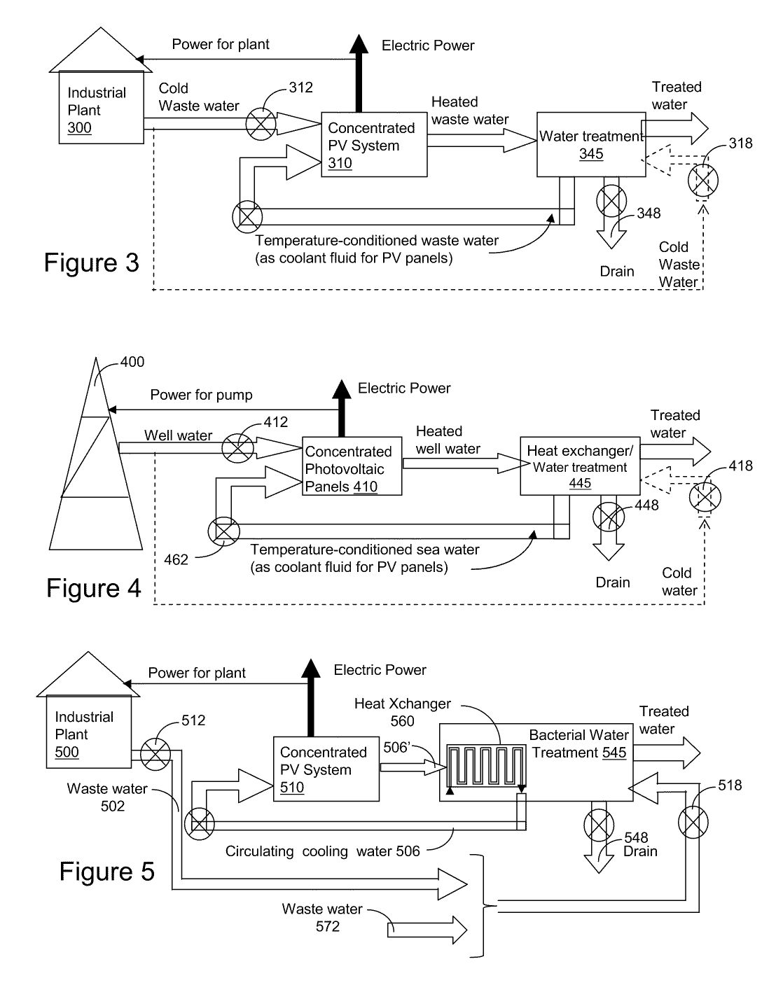

FIG. 3 illustrates an embodiment beneficial for operation at an industrial plant. As is known, often times industrial plants generate large quantities of waste water. Industrial plants also often require lots of energy and, in many cases, consume lots of energy during the normal working hours, e.g., daytime during the weekdays, but low energy during non-working hours, e.g., during nights and weekends. The embodiment illustrated in FIG. 3 is highly beneficial for such circumstances.

As shown in FIG. 3, the power grid of industrial plant 300 is coupled to the output of concentrated PV system 310. The system 310 has its top output at midday, when the plant 300 requires much of its power. In this manner, the plant may get its base power from the general grid, but its variable or peak power from the system 310. Also, waste water 312 from the plant is delivered to the PV system, as controlled by valve 312. The waste water cool the PV cells as explained with respect to the embodiment of FIG. 1. Also as shown in the prior embodiments, heated water can be mixed with the cold waste water prior to entering the PV system. As the waste water pass through the PV system it is heated and is then passed to treatment plant 345 to treat and reclaim the water. Notably, in this embodiment, the treatment need not result in potable water. Rather, the treatment may be sufficient to result in reclaimed water that may be used for non-consumption activities, e.g., irrigation, or for safe disposal into the main sewage or rain gutter system. If a complete separation is required between the PV cooling water and the treated water, then the water to be treated can be provided via valve 318, while the water supplied from valve 312 can be recirculated for cooling the PV or discarded via drain 348.

FIG. 4 illustrates an embodiment wherein the PV system is integrated into a water pumping facility and is used to both energize the water pump and for treating the pumped water. In FIG. 4 tower 400 schematically depicts a well water pump. The pump 400 is coupled to PV panels 410 and receives at least part of its consumed power from the PV system 410. At least part of the pumped water is supplied to the PV system via valve 412 as cooling fluid to cool the PV panels. The water heats up and is then delivered to treatment plant 445, wherein it can be treated by, e.g., high temperature RO system. Part of the heated water from the plant 445 may be circulated via valve 462 to control the temperature of the water entering the PV system 410, as explained above. Drain 448 is used to discard slurry and other contaminants removed from the treated water. As with the above embodiments, if a complete separation between the PV cooling water and the treated water is required, then a heat exchanger can be used at treatment plant 445, and the water to be treated can be supplied via valve 418.

FIG. 5 illustrates an embodiment wherein the PV system is integrated into an industrial plant and is used to heat a bacterial water treatment plant. Concentrated PV system 510 has water cooling implementation that can be similar to that described above, having circulating cooling water 506 used to cool the PV panels. The circulating water 506′ exit the PV system at elevated temperature and is directed to a heat exchanger 560, which is used to heat the bacterial treatment plant 545. The heat that is transferred into the bacterial treatment plant helps accelerate the bacterial treatment of the waste water. The waste water is provided via valve 518 and may be waste water 502 from the industrial plant 500 and/or waste water 572 obtained from other sources. As before, part or all of the energy generated by the PV system 510 may be used by the plant 500.

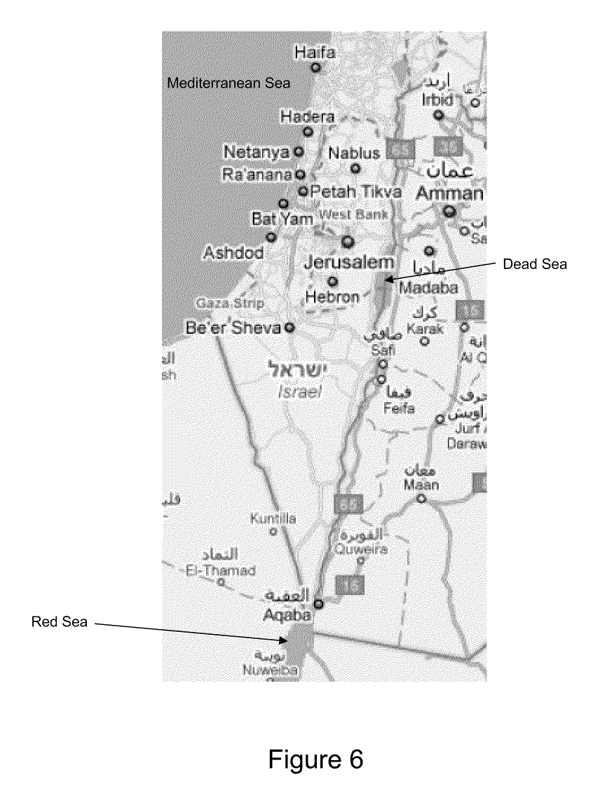

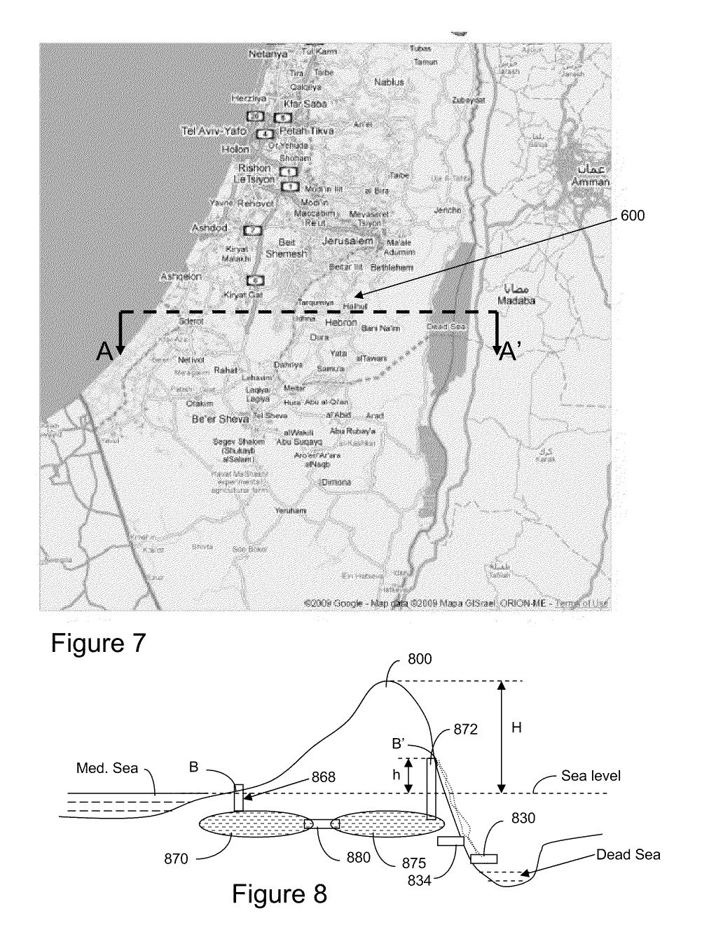

In some parts of the world, supply of fresh potable water is extremely scarce. One such region is the Negev and the Dead Sea area of Israel, shown on the map of FIG. 6. Various efforts have been conceptualized to bring less salty water from the Mediterranean sea to the Dead Sea area by running terrestrial pipeline between the two water bodies. Due to the topography of the region, the terrestrial pipelines need to climb up mountains adjoining the Dead Sea. Mountains 800, the Dead Sea, and the Mediterranean sea are schematically shown in FIG. 8. FIG. 8 is a not-to-scale cross-section along line A-A of FIG. 7, schematically illustrating an example embodiment of bringing sea water to a region with scarce supply of fresh water.

The existence of the mountains 800 has some advantages which are taken advantage of by the embodiment of FIG. 8. The Dead Sea is about 420 m below sea level. Adding the height H (or portion thereof ‘h’) of the mountain 800 to that, it is possible to generate substantial amount of hydro-electric power by letting the water fall down to a turbine 830 placed close to the level of the Dead Sea. However, using prior art scheme, this requires energy to pump up water against the gravity while climbing up the mountain 800 via the terrestrial pipeline.

To work around this problem of wasted energy overcoming gravity, the present inventor proposes using underground natural water repositories that have been found by geological survey approximately along the line AA′ in the map of Israel (and surrounding areas) shown in FIG. 7. These water repositories have substantially less salty water compared to the Dead Sea, and thus, a lesser degree of desalination is required to make the water potable. Schematically, two of the repositories 870 and 875 are shown. By digging approximately 150 m into the ground from point B′, water in the repository 875 is accessed through pipe 872. Location of point B′ and the corresponding height ‘h’ may be varied according to the target amount of power generation. Water drawn out of repository 875 is replenished from other natural bodies of water. For example, repository 875 may be naturally connected to the Mediterranean sea. Alternatively, repository 875 may be replenished by repository 870. Repositories 870 or 875 may be already connected via natural underground waterways. It is also possible to connect the repositories 870 and 875 by man-made connecting pipeline 880, if necessary. Repository 870 is replenished by bringing fresh water from the Mediterranean sea via pipeline 868 which may be terrestrial or underground. In case of terrestrial pipeline, about 20 m digging is necessary at point B to access repository 870.

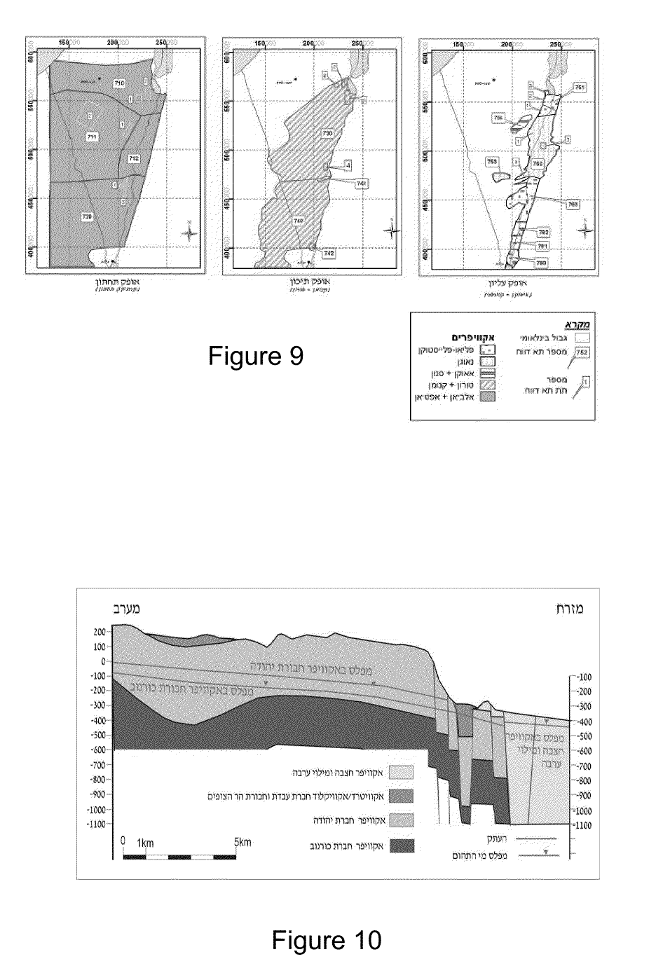

FIG. 9 represents the main aquifers in the Negev region from the Mediterranean Sea in the west to the Dead Sea on the east. It can be seen that the left picture shows the lower aquifer that covers most of the Negev area, above the lower aquifer. The middle picture shows the middle aquifer that exists on the east side, close to the Dead Sea. FIG. 10 represents a vertical hydrological cross-section of about 20 km, west to the Dead Sea. This cross section shows the levels of the two aquifers and their water level. According to one embodiment, a connection between the aquifers is made artificially in order to allow water from the Mediterranean Sea to flow east to the Dead Sea.

Persons skilled in the art will recognize that although in the above example, Israel is mentioned as the location, the present invention is suitable for any geographical area with similar topology and similar natural water resources.

In addition to the hydrogenation of electrical power, part of the water can also be desalinated. Conventional desalination methods may be used for a combined hydro-electricity generation and desalination system. The desalination can be done to two levels of desalination, one for generating reclaimed water that may be used for agriculture and other non-consumption uses, while the higher desalination level may be used for producing potable water for human and animal consumption.

Alternatively, FIG. 8 schematically illustrates concentrated PV system 834 is used for further generation of electrical power and treatment of water. The system 834 may be implemented as any of the systems shown in the above embodiments, such that the water that is pumped out of the repository 870 is used to cool the PV panels and then heated up and used to treat salted water that is also pumped from the repository 870. In this manner, some of the water pumped from repository 870 is used for hydro-electrical power generation, part is used to cool concentrated PV system, and part is treated and can be used for agriculture and human consumption.

Finally, it should be understood that processes and techniques described herein are not inherently related to any particular apparatus and may be implemented by any suitable combination of components. Further, various types of general purpose devices may be used in accordance with the teachings described herein. It may also prove advantageous to construct specialized apparatus to perform the method steps described herein. The present invention has been described in relation to particular examples, which are intended in all respects to be illustrative rather than restrictive. Those skilled in the art will appreciate that many different combinations of hardware, software, and firmware will be suitable for practicing the present invention.

Moreover, other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, with a true scope and spirit of the invention being indicated by the following claims.

What is claimed is:

1. A method comprising:
concentrating solar energy and directing the energy onto a photovoltaic system to thereby convert solar energy into electrical energy;
flowing recirculated water as a coolant fluid that absorbs heat from the photovoltaic system, thereby generating heated water;
directing the heated water coming out of the photovoltaic system into a water treatment system;
directing non-potable water into the water treatment system;
using heat from the heated water to treat the non-potable water to thereby produce treated water;
recirculating the heated water from the water treatment system back to the photovoltaic system.

2. The method of claim 1, wherein the non-potable water comprises sea water.

3. The method of claim 2, wherein treating the non-potable water comprises desalinating the non-potable water.

4. The method of claim 1, wherein using heat from the heated water comprises flowing the heated water into a heat exchanger.

5. The method of claim 1, further comprising conditioning temperature of the heated water prior to flowing recirculated water as a coolant fluid into the photovoltaic system.

6. The method of claim 5, wherein conditioning comprises mixing cold water with the heated water.

7. The method of claim 1, where the method further comprises:
directing the heated water coming out from the photovoltaic system to a solar heater that outputs steam and hot water, wherein the steam and the hot water are directed to a heat exchanger device.

8. The method of claim 1, wherein using heat from the heated water to treat the non-potable water comprises using the heat from the heated water to elevate the temperature of a reverse osmosis system.

9. The method of claim 1, wherein using heat from the heated water to treat the non-potable water comprises using the heat from the heated water to elevate the temperature of a bacterial water treatment system.

10. The method of claim 1, further comprising pumping underground water to obtain the non-potable water.

11. An installation for energy generation and water treatment, comprising:
an industrial plat generating waste water;
a concentrated photovoltaic system converting solar energy into electrical energy, the concentrated photovoltaic system receiving cooling water and outputting heated water;
a water treatment system receiving the heated water from the concentrated photovoltaic system and using heat from the heated water to treat non-potable water.

12. The installation of claim 11, wherein the non-potable water comprise waste water output by the industrial plant.

13. The installation of claim 11, wherein the water treatment system comprises a bacterial water treatment system.

14. The installation of claim 11, wherein the water treatment system comprises a high temperature reverse osmosis system.
